(19) United States
(12) Patent Application Publication
(10) Pub. No.: US 2010/0099243 A1
(43) Pub. Date: Apr. 22, 2010

(54) METHOD FOR FORMING DIODE IN PHASE CHANGE RANDOM ACCESS MEMORY DEVICE

(76) Inventors: Sun Hwan Hwang, Ichon-si (KR); Ki Seon Park, Ichon-si (KR); Ki Hong Lee, Ichon-si (KR)

Correspondence Address: IP & T Law Firm PLC, 7700 Little River Turnpike, Suite 207, Annandale, VA, 22003, US

(21) Appl. No.: 12/493,263

(22) Filed: Jun. 29, 2009

(30) Foreign Application Priority Data
Oct. 20, 2008 (KR) 10-2008-0102517

(51) Int. Cl. H01L 21/265

(52) U.S. Cl. 438/514; 257/E21.334

(57) ABSTRACT

A method for forming a diode of a phase change random access memory device includes preparing a semiconductor substrate having a dopant area formed thereon. An insulating layer on the semiconductor substrate is formed and a contact hole is formed by etching a part of the insulating layer such that a specific region of the dopant area is exposed. A silicon layer doped with a first-type dopant is formed in the contact hole. A part of the silicon layer is doped with a second-type dopant source gas through a gas cluster ion beam process.

### CROSS-REFERENCES TO RELATED APPLICATION

The present application claims priority under 35 U.S.C. 119(a) to Korean Application number 10-2008-0102517, filed on Oct. 20 2008, in the Korean Intellectual Property Office, which is incorporated herein by reference in its entirety as if set forth in full.

### BACKGROUND

1. Technical Field

The embodiments described herein relate to a method for forming a phase change random access memory device and, more particularly, to a method for forming a diode in a phase change random access memory device.

2. Related Art

The most serious problem in commercializing a phase change random access memory (PRAM) device is that a transistor, which is recently under development, cannot satisfy the condition for operating current of several millimeter amperes (mA) required to operate the PRAM device. In order to solve the above problem, studies and research have been actively performed to employ a diode as a switching element, instead of a transistor used in a conventional PRAM device, because the diode can serve as the transistor.

Meanwhile, metal silicide materials, such as cobalt silicide used as a lower electrode contact material and an inter-contact material, are stable and can provide polar resistance. In order to improve the operating current by reducing contact resistance of a high-integrated semiconductor device, there has been suggested a method for coating robust materials, such as metal silicide, on a contact interfacial surface to reduce the contact resistance between contact materials.

In order to form a metal silicide layer, interfacial reaction is required between contact materials. However, an abnormal surface may be formed through the interfacial reaction, so that contact resistance may be degraded. In addition, the degradation of the contact resistance may reduce the operating current so that malfunction of the diode may occur.

### SUMMARY

A method for forming a diode in a phase change random access memory device capable of improving the characteristics of operating current and contact resistance is described herein.

According to one aspect, a method for forming a diode of a phase change random access memory device includes preparing a semiconductor substrate having a dopant area formed thereon. An insulating layer on the semiconductor substrate is formed and a contact hole is formed by etching a part of the insulating layer such that a specific region of the dopant area is exposed. A silicon layer doped with a first-type dopant is formed in the contact hole. A part of the silicon layer is doped with a second-type dopant source gas through a gas cluster ion beam process.

According to another aspect, a method for forming a phase change random access memory device, includes preparing a semiconductor substrate having a cell area and a core area, wherein the cell area includes a dopant area formed thereon. An insulating layer is formed on the semiconductor substrate. A number of holes are formed by etching a number of parts of the insulating layer on the cell area such that a number of regions of the dopant area are exposed through the holes. A silicon layer doped with a first-type dopant is formed in each of the holes. A part of the silicon layer is doped with a second-type dopant source gas through a gas cluster ion beam process.

These and other features, aspects, and embodiments are described below in the section entitled “Detailed Description.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 3 are sectional views illustrating manufacturing processes according to one embodiment of the disclosure;

FIG. 4 is a view showing an example of a structure of a GCIB device according to an embodiment of the disclosure; and

FIG. 5 is a graph showing an activation distribution of dopants of a GCIB and a conventional ion beam process.

### DETAILED DESCRIPTION

First, a semiconductor substrate 110 is divided into a cell area and a core area by an isolation layer 100a. Although not shown in detail, a gate electrode structure including a gate insulating layer, a gate conductive layer, and spacers formed at sidewalls of the gate conductive layer is formed in the core area. A MOS transistor element 115 formed with a source/drain region (not shown) is provided on the semiconductor substrate 100 at both sides of the gate electrode structure.

Hereinafter, description will be made regarding a method for forming a phase change random access memory (PRAM) diode after the MOS transistor element 115 has been formed in the cell area.

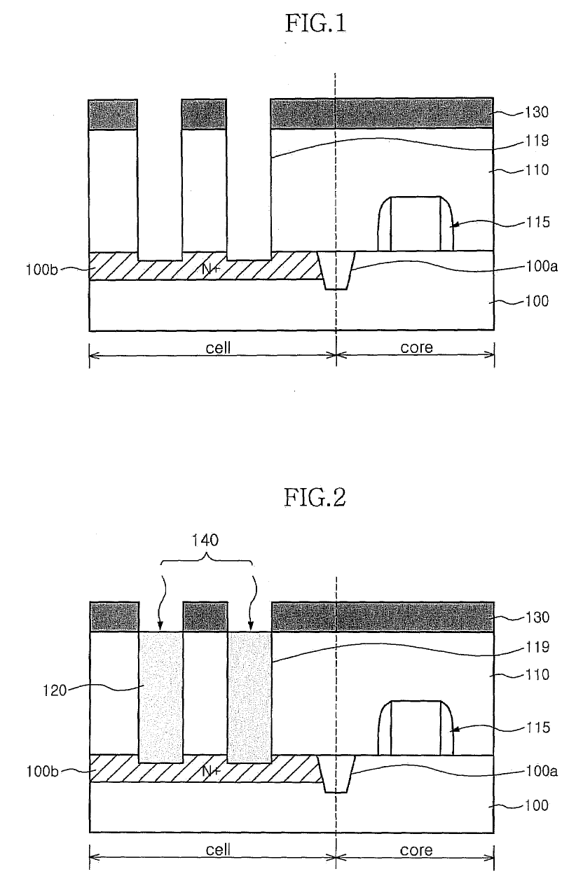

FIGS. 1 to 3 are sectional views illustrating manufacturing processes to form the PRAM diode according to one embodiment of the disclosure.

First, as shown in FIG. 1, first-type dopants (e.g., N-type dopants) are implanted into the cell area of the semiconductor substrate 100, thereby forming an N-type dopant area 100b. Thereafter, an insulating layer 110 is formed over the entire surface of the semiconductor substrate 100.

In this case, the insulating layer 110 may be formed by using oxides such as tetraethyl orthosilicate (TEOS), an undoped silicate glass (USG), a spin on glass (SOG), a flowable oxide (FOX), or an HDP-CVOD oxide. In addition, the insulating layer 110 may be formed through a chemical vapor deposition (CVD), a low pressure chemical vapor deposition (LPCVD), a plasma-enhanced chemical vapor deposition (PECVD), or a plasma enhanced chemical vapor deposition (HPCVD).

Subsequently, a photoresist pattern 130 is formed on the insulating layer 110. Thereafter, a specific portion of the insulating layer 115 is etched by using the photoresist pattern 130 as a photomask. Accordingly, a contact hole 119 is formed to expose the dopant area 100b.

Thereafter, as shown in FIG. 2, a silicon layer 120 doped with the first-type dopants (e.g., N-type dopants) is filled in the contact hole 119. The silicon layer 120 may include a poly-silicon is layer or a single crystalline silicon layer.

Next, a second-type dopant doping process 140 is performed with respect to the silicon layer 120 doped with the N-type dopants by using a second-type gas cluster source (e.g., P-type gas cluster source).

In this case, the P-type dopant source gas may be one selected from the group consisting of compound of boron trifluoride (BF₃) and argon (Ar) gases, compound of diborane (B₂H₆) and argon (Ar) gases, compound of boron trifluoride (BF₃), nitrogen trifluoride (NF₃) and oxygen gases, and compound of diborane (B₂H₆), nitrogen trifluoride (NF₃) and oxygen (O₂) gases.

A plasma doping process, a cluster ion beam process, or a gas cluster ion beam (GCIB) process may be used as the P-type dopant doping process 140. According to the present embodiment, the GCIB process is used as the P-type dopant doping process 140.

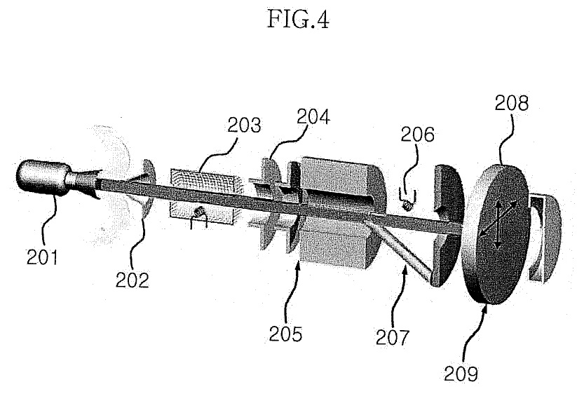

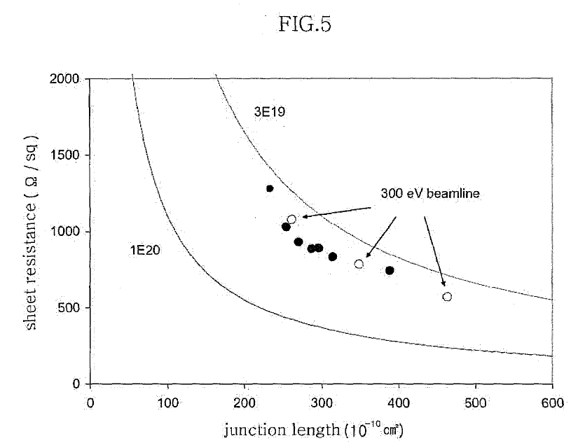

Hereinafter, a GCIB device will be schematically described with reference to FIG. 4.

First, the GCIB device irradiates several hundreds to thousands of gas clusters, which are ionized through adiabatic expansion, on a target after accelerating the gas clusters. The GCIB device provides process parameters defined according to acceleration voltage and an amount of irradiated ions. When the GCIB device is used, the uniformity and regeneration of products having the same level as that of the ion implantation process can be obtained.

To this end, the GCIB device filters a monomer ion beam when generating a cluster ion beam. The GCIB device mainly employs argon (Ar), which is an inert gas, as a source material.

In the case of the GCIB device employing the inert gas, such as Ar, cluster ions that apply impact to the target may cause a rebound effect. This is useful to clean the target while providing atomic level smoothness to the target.

When a source material, such as an oxygen (O₂) gas, a nitrogen (N₂) gas, a carbon tetrafluoride (CF₄) gas, a sulfur hexafluoride (SF₆) gas, or a fluorine (F₂) gas, which reacts with the target, is employed, the local variation of a temperature and pressure made by impact of the clusters causes a very effective chemical reaction between cluster atoms and atoms of the target.

Such a use of the GCIB device may implement an ion-free process. In addition, since 5000 or more atoms are contained in one charge, superior productivity can be achieved, and an ion implantation process can be performed with respect to an ultra-shallow surface of 20 nm or less.

Reference numerals 201, 202, 203, 204, 205, 206, 207, 208, and 209 of FIG. 4 represent a nozzle, a skimmer, an ionizer, a beam optical instrument, a magnetic filter, a beam neutralizer, an iris, a mechanical scanner, and a faraday current monitor, respectively.

The clusters can be generated based on various kinds of gases including Ar, O₂, or N₂ and mixed gases such as CF₄ or SF₆, which react with Ar, O₂, or N₂, according to the use purpose of the clusters.

First, in the first vacuum step, when the source gas, which is provided from the nozzle 201 under a high pressure at a supersonic speed, is expanded in a vacuum state, neutralization clusters are created.

The neutralization clusters that have entered the second vacuum state through the skimmer 202 are bombarded by electrons, so that the neutralization clusters are ionized and then accelerated at high energy in a range of several kVs to several tens kVs suitably for the use of an extracted beam. Monomer ions are filtered from the extracted beam through the magnetic filter 205, so the clusters having the size distribution of several hundreds to several thousands atoms may remain in the beam.

In the third vacuum step, the mechanical scanner 208 is used to uniformly treat the target. The faraday current monitor 209 adjusts an amount of irradiated ions. A system has a robot to handle the target such that the target can be adjusted relative to a beam. Through the above procedure, a gas cluster ion beam is generated.

According to one embodiment, in order to stably perform a doping concentration, the temperature, that is, a process temperature of a chiller, which is a substrate support member, is maintained within the range of about 10° C. to 500□. Implant energy is within the range of about 5 Kev to 80 Kev, and implant doze is in the range of about 1×10¹¹/Cm² to 5.0×10¹⁷/Cm².

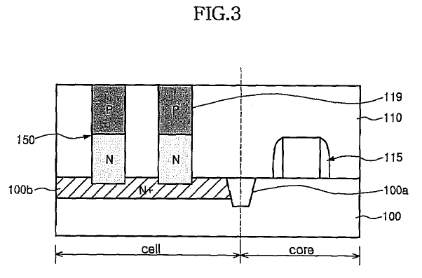

Thereafter, as shown in FIG. 3, the photoresist pattern 130 remaining on the insulating layer 110 and used as a hard mask is removed through an ashing process or a striping process. Accordingly, a PN diode 150 doped with the P-type dopant source gas through the gas cluster ion beam process is formed.

The subsequence processes are similar to the processes for forming a typical PRAM.

FIG. 5 is a graph showing an activation distribution of dopants through the typical ion beam process and the GCIB.

Referring to FIG. 5, when GCIB ion implantation energy for boron or boron fluoride (BF₂) is about 300 eV, dopants become more activated through the GCIB process as compared with the typical ion beam process. In this case, an X axis represents a junction length (10⁻¹⁰ cm²), and a Y axis represents sheet resistance (Ω/sq).

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A method for forming a diode of a phase change random access memory device, the method comprising:
preparing a semiconductor substrate having a dopant area formed thereon;
forming an insulating layer on the semiconductor substrate;
forming a contact hole by etching a part of the insulating layer such that a region of the dopant area is exposed;
forming a silicon layer doped with a first-type dopant in the contact hole; and
doping a part of the silicon layer with a second-type dopant source gas through a gas cluster ion beam process.

2. The method of claim 1, wherein the second-type dopant source gas comprises P-type cluster ions and an inert gas.

3. The method of claim 2, wherein the second-type dopant source gas comprises diborane (B₂H₆) and argon (Ar) gases.

4. The method of claim 2, wherein the second-type dopant source gas comprises boron trifluoride (BF₃) and argon (Ar) gases.

5. The method of claim 2, wherein the second-type dopant source gas comprises diborane (B₂H₆), nitrogen trifluoride (NF₃), and oxygen (O₂) gases.

6. The method of claim 2, wherein the second-type dopant source gas comprises boron trifluoride (BF₃), nitrogen trifluoride (NF₃), and oxygen (O₂) gases.

7. The method of claim 2, wherein the second-type dopant source gas is doped at a temperature in a range of about 10° C. to 500° C.

8. The method of claim 2, wherein the second-type dopant source gas is doped under energy in a range of about 5 KeV to 80 KeV.

9. The method of claim 2, wherein the second-type dopant source gas is doped at a concentration in a range of about 1×10¹¹/Cm² to 5.0×10¹⁷/Cm².

10. A method for forming a phase change random access memory device, the method comprising:
preparing a semiconductor substrate having a cell area and a core area, wherein the cell area includes a dopant area formed thereon;
forming an insulating layer on the semiconductor substrate;
forming a number of holes by etching a number of parts of the insulating layer on the cell area such that a number of regions of the dopant area are exposed through the holes;
forming a silicon layer doped with a first-type dopant in each of the holes; and
doping a part of the silicon layer with a second-type dopant source gas through a gas cluster ion beam process.

11. The method of claim 10, wherein the second-type dopant source gas comprises P-type cluster ions and an inert gas.

12. The method of claim 11, wherein the second-type dopant source gas comprises diborane (B₂H₆) and argon (Ar) gases.

13. The method of claim 11, wherein the second-type dopant source gas comprises boron trifluoride (BF₃) and argon (Ar) gases.

14. The method of claim 11, wherein the second-type dopant source gas comprises diborane (B₂H₆), nitrogen trifluoride (NF₃), and oxygen (O₂) gases.

15. The method of claim It, wherein the second-type dopant source gas comprises boron trifluoride (BF₃), nitrogen trifluoride (NF₃), and oxygen (O₂) gases.
